(19) United States
(12) Patent Application Publication
(10) Pub. No.: US 2025/0285797 A1
(43) Pub. Date: Sep. 11, 2025

(54) TRANSFORMER AND HIGH-FREQUENCY MODULE

(71) Applicant: Murata Manufacturing Co., Ltd., Kyoto-fu (JP)

(72) Inventors: Tomoya ODA, Nagaokakyo-shi (JP); Tetsurou ASHIDA, Nagaokakyo-shi (JP); Kazuhiro IKARASHI, Nagaokakyo-shi (JP); Kensuke TAKIMOTO, Nagaokakyo-shi (JP); Ikuo TAMARU, Nagaokakyo-shi (JP); Naoya MURAKITA, Nagaokakyo-shi (JP)

(73) Assignee: Murata Manufacturing Co., Ltd., Kyoto-fu (JP)

(21) Appl. No.: 19/069,821

(22) Filed: Mar. 4, 2025

(30) Foreign Application Priority Data
Mar. 6, 2024 (JP) 2024-033620

(51) Int. Cl. H01F 27/28; H01F 27/29; H03F 3/24

(52) U.S. Cl. CPC H01F 27/2804; H01F 27/29; H03F 3/245; H01F 2027/2809

(57) ABSTRACT

A transformer at a multilayer substrate having a plurality of wiring layers laminated with a dielectric layer interposed therebetween has a balanced-side coil between a first terminal and a second terminal and an unbalanced-side coil between a third terminal and a fourth terminal. The balanced-side coil is configured such that a first inductor and a second inductor at different ones of the wiring layers are connected in parallel. The unbalanced-side coil is configured such that a third inductor and a fourth inductor at different ones of the wiring layers are connected in series.

### CROSS-REFERENCE TO RELATED APPLICATION

This application claims benefit of priority to Japanese Patent Application No. 2024-033620, filed Mar. 6, 2024, the entire content of which is incorporated herein by reference.

### BACKGROUND

### Technical Field

The present disclosure relates to a transformer and a high-frequency module.

### Background Art

There is known a power amplifier with a configuration such that differential signals are synthesized by a transformer as described, for example, Japanese Unexamined Patent Application Publication No. 2010-147574. The transformer used in the power amplifier described in Japanese Unexamined Patent Application Publication No. 2010-147574 includes: a primary coil which has the neutral point to which a power supply voltage is supplied and which receives input of differential signals; and a secondary coil which is grounded at its first end, is electromagnetically coupled to the primary coil, and outputs a synthesized signal of the differential signals from a second end.

In the power amplifier with the configuration described above, increasing the ratio of windings of the primary coil and the secondary coil with an attempt to achieve a higher output may result in a size increase of the transformer or an increase in power loss. International Publication No. WO2023/127387 discloses a technique for enabling less size increase of a transformer or less power loss by providing a balanced-side coil (a primary coil) and an unbalanced-side coil (a secondary coil) over a plurality of layers of a multilayer substrate.

### SUMMARY

In the configuration in International Publication No. WO2023/127387, a balanced-side coil and an unbalanced-side coil are formed such that coils extending over a plurality of layers are electrically connected in series. In recent years, there are demands for a transformer which enables a power amplifier to support an even higher frequency or output.

The present disclosure has been made in view of the above circumstances and aims to achieve a transformer and a high-frequency module capable of implementing a differential power amplification circuit supporting a higher frequency or output.

A transformer according to one aspect of the present disclosure is a transformer provided at a multilayer substrate having a plurality of wiring layers laminated with a dielectric layer interposed in between. The transformer includes a balanced-side coil provided between a first terminal and a second terminal and an unbalanced-side coil provided between a third terminal and a fourth terminal. The balanced-side coil is configured such that a first inductor and a second inductor provided at different ones of the wiring layers are connected in parallel, and the unbalanced-side coil is configured such that a third inductor and a fourth inductor provided at different ones of the wiring layers are connected in series.

This configuration allows the inductance value of the balanced-side coil to be small relative to the inductance value of the unbalanced-side coil. This can increase the impedance transformation ratio of the transformer.

It is also possible to move a point of resonance of a resonance circuit caused by interwinding capacitance to a higher frequency side. The pass band can thus be widened to the higher-frequency side.

A high-frequency module according to one aspect of the present disclosure is a high-frequency module including the above transformer and a power amplification circuit including a first amplifier and a second amplifier. In the transformer, a first balanced signal outputted from the first amplifier is inputted to the first terminal, a second balanced signal outputted from the second amplifier is inputted to the second terminal, the fourth terminal is connected to a ground potential, a DC power supply potential is supplied to the fifth terminal, and an unbalanced signal obtained by synthesis of the first balanced signal and the second balanced signal is outputted from the third terminal.

This configuration allows the inductance value of the balanced-side coil to be small relative to the inductance value of the unbalanced-side coil. This can increase the impedance transformation ratio of the transformer and can consequently increase the output of power amplification by the high-frequency module.

It is also possible to move a point of resonance of a resonance circuit caused by interwinding capacitance to a higher frequency side. The pass band can thus be widened to the higher-frequency side.

A high-frequency module according to one aspect of the present disclosure is a high-frequency module including the above transformer and a power amplification circuit including a first amplifier and a second amplifier. In the transformer, a first balanced signal outputted from the first amplifier is inputted to the first terminal, a second balanced signal outputted from the second amplifier is inputted to the second terminal, a DC power supply potential is supplied to the fourth terminal, and an unbalanced signal obtained by synthesis of the first balanced signal and the second balanced signal is outputted from the third terminal.

This configuration allows the inductance value of the balanced-side coil to be small relative to the inductance value of the unbalanced-side coil. This can increase the impedance transformation ratio of the transformer and can consequently increase the output of power amplification by the high-frequency module.

It is also possible to move a point of resonance of a resonance circuit caused by interwinding capacitance to a higher frequency side. The pass band can thus be widened to the higher-frequency side.

The present disclosure can achieve a transformer and a high-frequency module capable of implementing a differential power amplification circuit supporting a higher frequency or output.

### BRIEF DESCRIPTION OF THE DRAWINGS

FIG. 1 is a schematic diagram showing an example circuit block configuration of a high-frequency module according to Embodiment 1;

FIG. 2 is a sectional view showing an example of a multilayer substrate where a transformer according to Embodiment 1 is mounted;

FIG. 3 is a plan view showing a first specific example of a balanced-side coil and an unbalanced-side coil provided in wiring layers of a multilayer substrate of the transformer according to Embodiment 1;

FIG. 4A is an overlapping see-through view of a first wiring layer and a second wiring layer in the first specific example of Embodiment 1;

FIG. 4B is an overlapping see-through view of a third wiring layer and a fourth wiring layer in the first specific example of Embodiment 1;

FIG. 5 is a plan view showing a second specific example of the balanced-side coil and the unbalanced-side coil provided in the wiring layers of the multilayer substrate of the transformer according to Embodiment 1;

FIG. 6A is an overlapping see-through view of the first wiring layer and the second wiring layer in the second specific example of Embodiment 1;

FIG. 6B is an overlapping see-through view of the third wiring layer and the fourth wiring layer in the second specific example of Embodiment 1;

FIG. 7 is a plan view showing a third specific example of the balanced-side coil and the unbalanced-side coil provided in the wiring layers of the multilayer substrate of the transformer according to Embodiment 1;

FIG. 8A is an overlapping see-through view of the first wiring layer and the second wiring layer in the third specific example of Embodiment 1;

FIG. 8B is an overlapping see-through view of the third wiring layer and the fourth wiring layer in the third specific example of Embodiment 1;

FIG. 9 is a plan view showing a fourth specific example of the balanced-side coil and the unbalanced-side coil provided in the wiring layers of the multilayer substrate of the transformer according to Embodiment 1;

FIG. 10A is an overlapping see-through view of the first wiring layer and the second wiring layer in the fourth specific example of Embodiment 1;

FIG. 10B is an overlapping see-through view of the third wiring layer and the fourth wiring layer in the fourth specific example of Embodiment 1;

FIG. 11 is a schematic diagram showing an example circuit block configuration of a high-frequency module according to Embodiment 2;

FIG. 12 is a plan view showing a first specific example of a balanced-side coil and an unbalanced-side coil provided in wiring layers of a multilayer substrate of a transformer according to Embodiment 2;

FIG. 13A is an overlapping see-through view of a first wiring layer and a second wiring layer in the first specific example of Embodiment 2;

FIG. 13B is an overlapping see-through view of a third wiring layer and a fourth wiring layer in the first specific example of Embodiment 2;

FIG. 14 is a plan view showing a second specific example of the balanced-side coil and the unbalanced-side coil provided in the wiring layers of the multilayer substrate of the transformer according to Embodiment 2;

FIG. 15A is an overlapping see-through view of the first wiring layer and the second wiring layer in the second specific example of Embodiment 2;

FIG. 15B is an overlapping see-through view of the third wiring layer and the fourth wiring layer in the second specific example of Embodiment 2;

FIG. 16 is a plan view showing a third specific example of the balanced-side coil and the unbalanced-side coil provided in the wiring layers of the multilayer substrate of the transformer according to Embodiment 2;

FIG. 17A is an overlapping see-through view of the first wiring layer and the second wiring layer in the third specific example of Embodiment 2;

FIG. 17B is an overlapping see-through view of the third wiring layer and the fourth wiring layer in the third specific example of Embodiment 2;

FIG. 18 is a plan view showing a fourth specific example of the balanced-side coil and the unbalanced-side coil provided in the wiring layers of the multilayer substrate of the transformer according to Embodiment 2;

FIG. 19A is an overlapping see-through view of the first wiring layer and the second wiring layer in the fourth specific example of Embodiment 2;

FIG. 19B is an overlapping see-through view of the third wiring layer and the fourth wiring layer in the fourth specific example of Embodiment 2; and

FIG. 20 is a plan view showing an example arrangement of components on a multilayer substrate of a high-frequency module according to a modification of Embodiment 2.

### DETAILED DESCRIPTION

Transformers and high-frequency modules according to embodiments are described in detail below based on the drawings. Note that the present disclosure is not limited to these embodiments.

### Embodiment 1

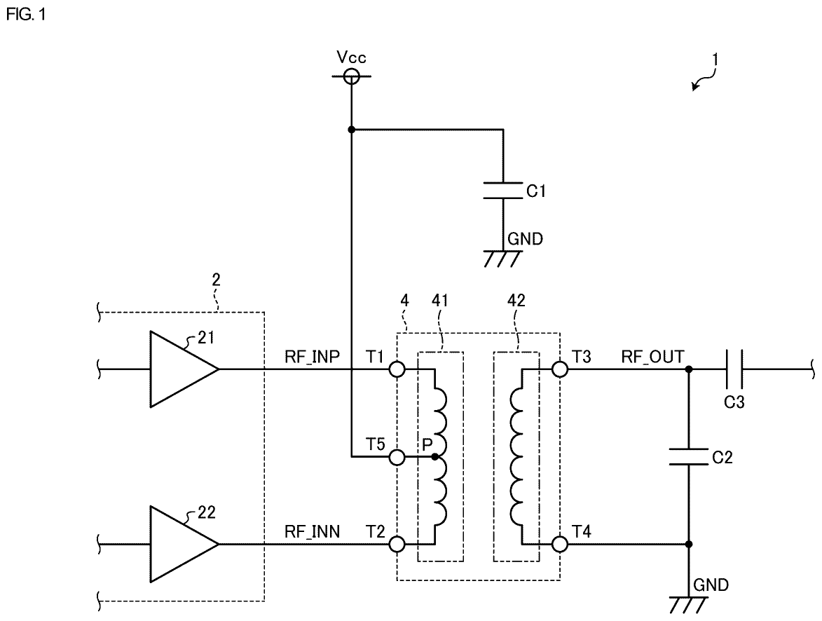

FIG. 1 is a schematic diagram showing an example circuit block configuration of a high-frequency module according to Embodiment 1. A high-frequency module 1 according to the present embodiment is a microminiature integrated module integrating a plurality of integrated circuits and various functional components mounted on a ceramic multilayer substrate such as, for example, a low temperature co-fired ceramics (LTCC) substrate.

In the example shown in FIG. 1, the high-frequency module 1 includes a power amplification circuit 2, a transformer 4, and capacitors C1, C2, and C3.

The power amplification circuit 2 is a chip device mounted on, for example, an LTCC substrate. The power amplification circuit 2 may be formed of, for example, a bipolar transistor or may be formed of, for example, a field effect transistor (FET). If the power amplification circuit 2 is formed of a bipolar transistor, a heterojunction bipolar transistor (HBT) is an example.

The power amplification circuit 2 includes a first amplifier 21 and a second amplifier 22. An example of the power amplification circuit 2 is a differential Doherty amplification circuit. In this case, the first amplifier 21 and the second amplifier 22 may each be configured including a carrier amplifier and a peaking amplifier.

The transformer 4 according to Embodiment 1 includes a balanced-side coil 41 and an unbalanced-side coil 42. The balanced-side coil 41 and the unbalanced-side coil 42 are electromagnetically coupled.

A first end of the balanced-side coil 41 (a first terminal T1) receives input of a first balanced signal RF_INP outputted from the first amplifier 21. A second end of the balanced-side coil 41 (a second terminal T2) receives input of a second balanced signal RF_INN outputted from the second amplifier 22.

A DC power supply potential VCC is supplied to a center tap P of the balanced-side coil 41 (a fifth terminal T5). The capacitor C1 is provided between a supply path of the DC power supply potential VCC and a ground potential GND. The capacitor C1 is a smoothing capacitor that removes a high-frequency noise component contained in the DC power supply potential VCC.

An unbalanced signal RF_OUT is outputted from a first end of the unbalanced-side coil 42. A second end of the unbalanced-side coil 42 (a fourth terminal T4) is connected to the ground potential GND.

The capacitors C2, C3 are components constituting an output matching circuit. Note that the output matching circuit may be configured including not only the capacitors C2, C3, but also the transformer 4.

In the configuration shown in FIG. 1, the transformer 4 transforms the first balanced signal RF_INP inputted from the first terminal T1 and the second balanced signal RF_INN inputted from the second terminal T2 into the unbalanced signal RF_OUT by synthesizing them and outputs the unbalanced signal RF_OUT from a third terminal T3.

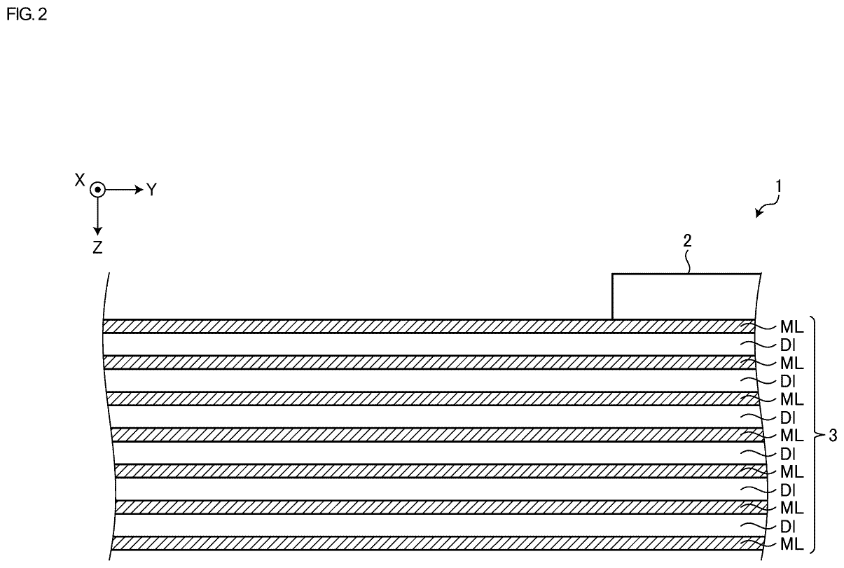

The following describes specific examples of the configuration of the high-frequency module 1 according to the embodiment where the balanced-side coil 41 and the unbalanced-side coil 42 of the transformer 4 are provided in wiring layers of a multilayer substrate. FIG. 2 is a sectional view showing an example of the multilayer substrate where the transformer according to Embodiment 1 is mounted. FIG. 2 shows a section taken along a YZ-plane orthogonal to a XY-plane, which corresponds to a component mount surface of the high-frequency module 1 where the power amplification circuit 2 as seen in a plan view from a Z-direction.

In the configuration shown in FIG. 2, the balanced-side coil 41 and the unbalanced-side coil 42 of the transformer 4 are provided at a multilayer substrate 3 having a plurality of wiring layers ML laminated with a dielectric layer DI in between. The multilayer substrate 3 is formed of, for example, a ceramic multilayer substrate such as an LTCC substrate.

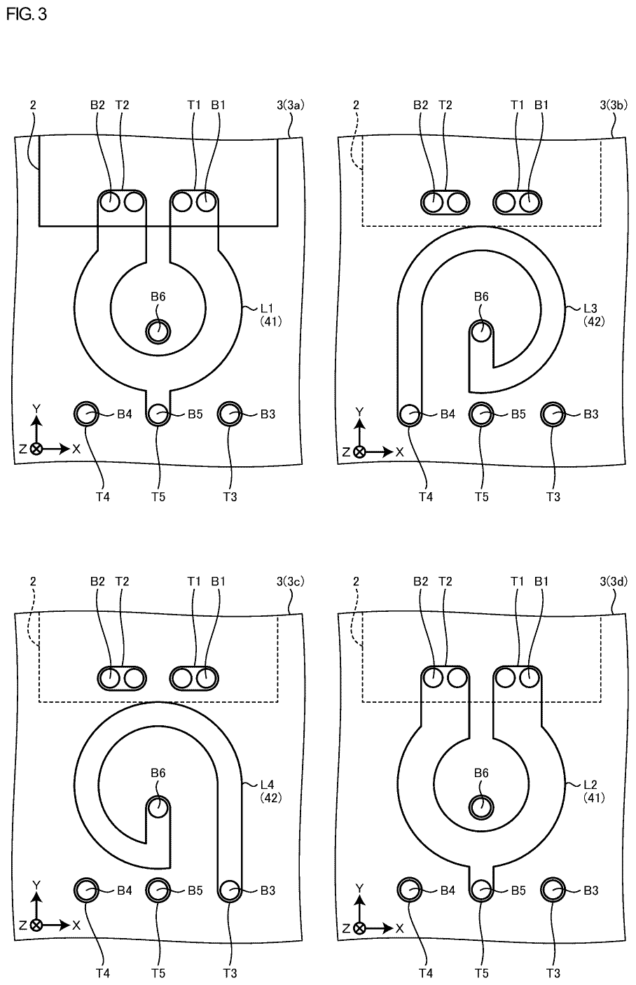

FIG. 3 is a plan view showing a first specific example of the balanced-side coil and the unbalanced-side coil provided in the wiring layers of the multilayer substrate of the transformer according to Embodiment 1. Here, the wiring layer ML provided at a surface layer of the multilayer substrate 3 (which is the component mount surface of the high-frequency module 1 in this example) is a first wiring layer 3a, the wiring layer ML provided on the first wiring layer 3a with a dielectric layer DI interposed therebetween is a second wiring layer 3b, the wiring layer ML provided on the second wiring layer 3b with a dielectric layer DI interposed therebetween is a third wiring layer 3c, and the wiring layer ML provided on the third wiring layer 3c with a dielectric layer DI interposed therebetween is a fourth wiring layer 3d.

In the first specific example shown in FIG. 3, a first inductor L1 at the first wiring layer 3a and a second inductor L2 at the fourth wiring layer 3d are provided in parallel between the first terminal T1 and the second terminal T2.

Specifically, the first inductor L1 at the first wiring layer 3a and the second inductor L2 at the fourth wiring layer 3d are electrically connected by a via B1 provided at the first terminal T1.

Also, the first inductor L1 at the first wiring layer 3a and the second inductor L2 at the fourth wiring layer 3d are electrically connected by a via B2 provided at the second terminal T2.

Also, the first inductor L1 at the first wiring layer 3a and the second inductor L2 at the fourth wiring layer 3d are electrically connected by a via B5 provided at the fifth terminal T5.

The balanced-side coil 41 is thus configured as a parallel circuit of the first inductor L1 at the first wiring layer 3a and the second inductor L2 at the fourth wiring layer 3d.

Also, in the first specific example shown in FIG. 3, a third inductor L3 at the second wiring layer 3b and a fourth inductor L4 at the third wiring layer 3c are provided in series between the third terminal T3 and the fourth terminal T4.

Specifically, the third inductor L3 at the second wiring layer 3b and the fourth inductor L4 at the third wiring layer 3c are electrically connected by a via B6.

The unbalanced-side coil 42 is thus configured as a series circuit of the third inductor L3 at the second wiring layer 3b and the fourth inductor L4 at the third wiring layer 3c.

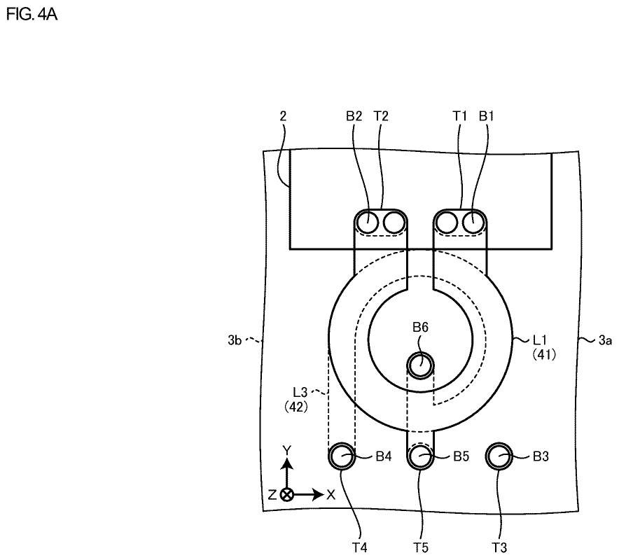

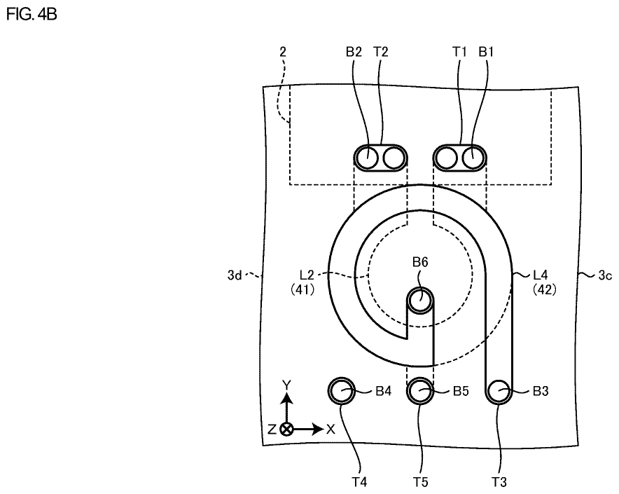

FIG. 4A is an overlapping see-through view of the first wiring layer and the second wiring layer in the first specific example of Embodiment 1. FIG. 4B is an overlapping see-through view of the third wiring layer and the fourth wiring layer in the first specific example of Embodiment 1.

As shown in FIG. 4A, the first inductor L1 of the balanced-side coil 41 provided at the first wiring layer 3a and the third inductor L3 of the unbalanced-side coil 42 provided at the second wiring layer 3b overlap in the Z-direction with the dielectric layer DI interposed therebetween. The first inductor L1 and the third inductor L3 are thereby electromagnetically coupled.

Also, as shown in FIG. 4B, the fourth inductor L4 of the unbalanced-side coil 42 provided at the third wiring layer 3c and the second inductor L2 of the balanced-side coil 41 provided at the fourth wiring layer 3d overlap in the Z-direction with the dielectric layer DI interposed therebetween. The fourth inductor L4 and the second inductor L2 are thereby electromagnetically coupled.

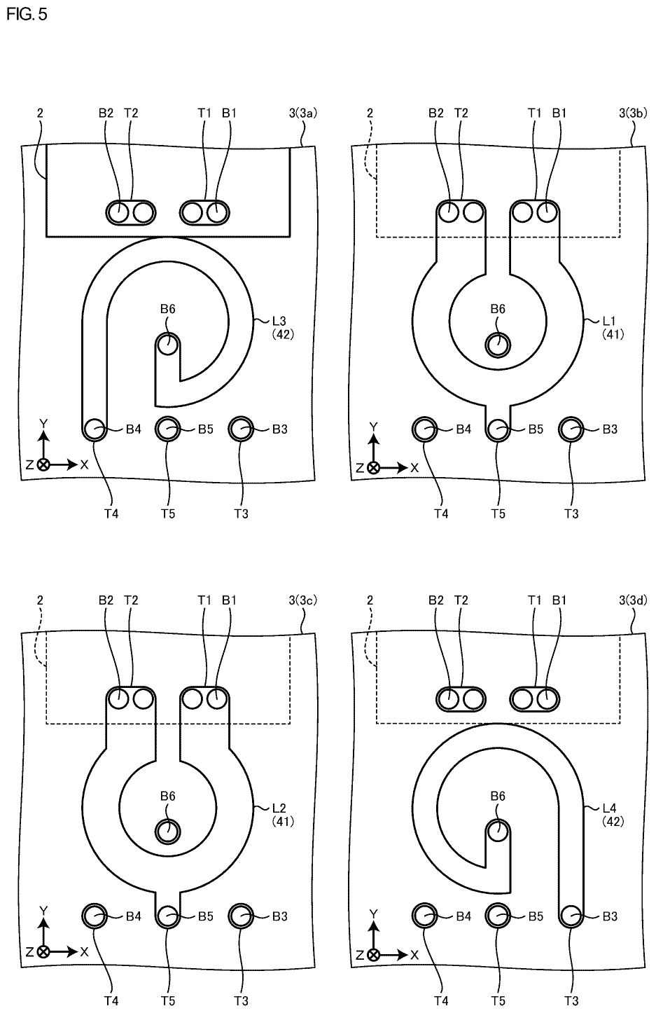

FIG. 5 is a plan view showing a second specific example of the balanced-side coil and the unbalanced-side coil provided in the wiring layers of the multilayer substrate of the transformer according to Embodiment 1.

In the second specific example shown in FIG. 5, the first inductor L1 at the second wiring layer 3b and the second inductor L2 at the third wiring layer 3c are provided in parallel between the first terminal T1 and the second terminal T2.

Specifically, the first inductor L1 at the second wiring layer 3b and the second inductor L2 at the third wiring layer 3c are electrically connected by the via B1 provided at the first terminal T1.

Also, the first inductor L1 at the second wiring layer 3b and the second inductor L2 at the third wiring layer 3c are electrically connected by the via B2 provided at the second terminal T2.

Also, the first inductor L1 at the second wiring layer 3b and the second inductor L2 at the third wiring layer 3c electrically connected by the via B5 provided at the fifth terminal T5.

The balanced-side coil 41 is thus configured as a parallel circuit of the first inductor L1 at the second wiring layer 3b and the second inductor L2 at the third wiring layer 3c.

Also, in the second specific example shown in FIG. 5, the third inductor L3 at the first wiring layer 3a and the fourth inductor L4 at the fourth wiring layer 3d are provided in series between the third terminal T3 and the fourth terminal T4.

Specifically, the third inductor L3 at the first wiring layer 3a and the fourth inductor L4 at the fourth wiring layer 3d are electrically connected by the via B6.

The unbalanced-side coil 42 is thus configured as a series circuit of the third inductor L3 at the first wiring layer 3a and the fourth inductor L4 at the fourth wiring layer 3d.

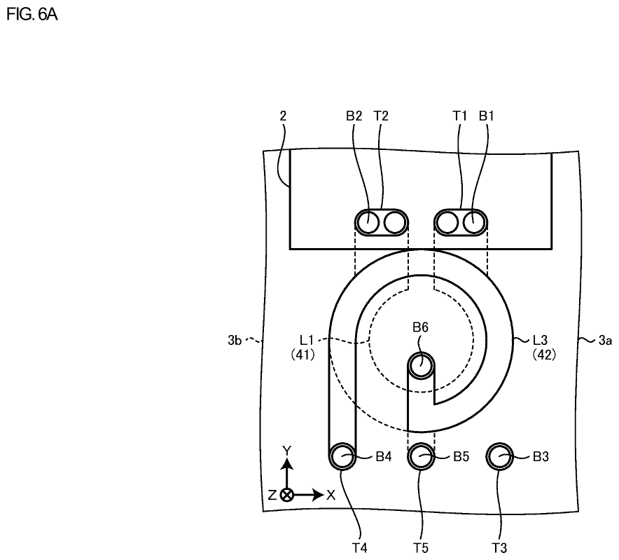

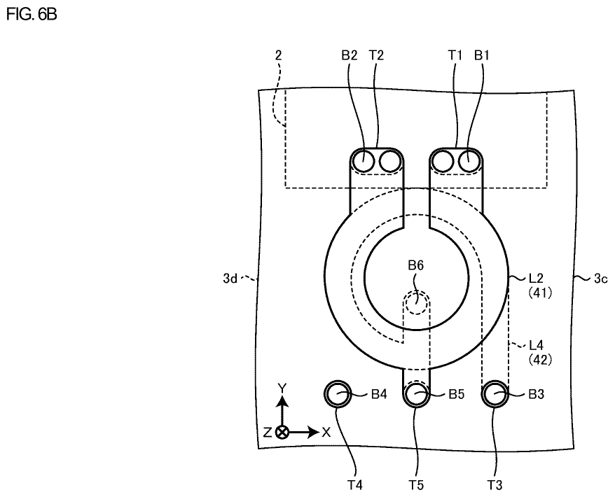

FIG. 6A is an overlapping see-through view of the first wiring layer and the second wiring layer in the second specific example of Embodiment 1. FIG. 6B is an overlapping see-through view of the third wiring layer and the fourth wiring layer in the second specific example of Embodiment 1.

As shown in FIG. 6A, the third inductor L3 of the unbalanced-side coil 42 provided at the first wiring layer 3a and the first inductor L1 of the balanced-side coil 41 provided at the second wiring layer 3b overlap in the Z-direction with the dielectric layer DI interposed therebetween. The third inductor L3 and the first inductor L1 are thereby electromagnetically coupled.

Also, as shown in FIG. 6B, the second inductor L2 of the balanced-side coil 41 provided at the third wiring layer 3c and the fourth inductor L4 of the unbalanced-side coil 42 provided at the fourth wiring layer 3d overlap in the Z-direction with the dielectric layer DI interposed therebetween. The second inductor L2 and the fourth inductor L4 are thereby electromagnetically coupled.

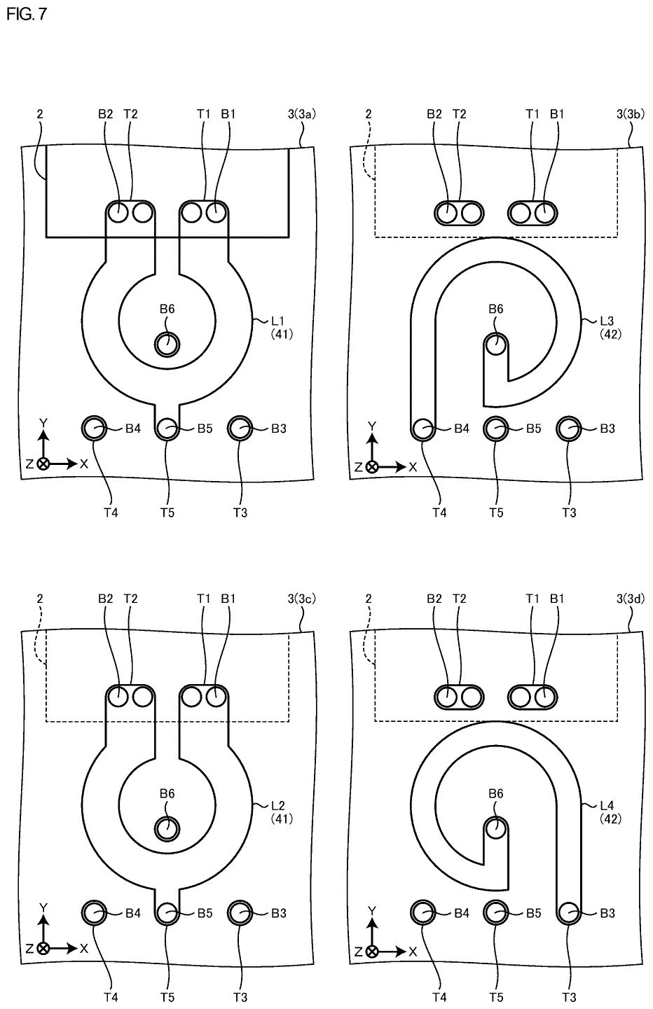

FIG. 7 is a plan view showing a third specific example of the balanced-side coil and the unbalanced-side coil provided in the wiring layers of the multilayer substrate of the transformer according to Embodiment 1.

In the third specific example shown in FIG. 7, the first inductor L1 at the first wiring layer 3a and the second inductor L2 at the third wiring layer 3c are provided in parallel between the first terminal T1 and the second terminal T2.

Specifically, the first inductor L1 at the first wiring layer 3a and the second inductor L2 at the third wiring layer 3c are electrically connected by the via B1 provided at the first terminal T1.

Also, the first inductor L1 at the first wiring layer 3a and the second inductor L2 at the third wiring layer 3c are electrically connected by the via B2 provided at the second terminal T2.

Also, the first inductor L1 at the first wiring layer 3a and the second inductor L2 at the third wiring layer 3c are electrically connected by the via B5 provided at the fifth terminal T5.

The balanced-side coil 41 is thus configured as a parallel circuit of the first inductor L1 at the first wiring layer 3a and the second inductor L2 at the third wiring layer 3c.

Also, in the third specific example shown in FIG. 7, the third inductor L3 at the second wiring layer 3b and the fourth inductor L4 at the fourth wiring layer 3d are provided in series between the third terminal T3 and the fourth terminal T4.

Specifically, the third inductor L3 at the second wiring layer 3b and the fourth inductor L4 at the fourth wiring layer 3d are electrically connected by the via B6.

The unbalanced-side coil 42 is thus configured as a series circuit of the third inductor L3 at the second wiring layer 3b and the fourth inductor L4 at the fourth wiring layer 3d.

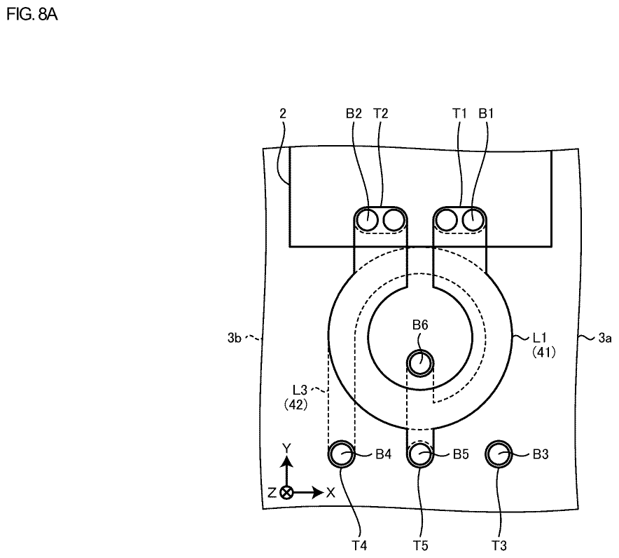

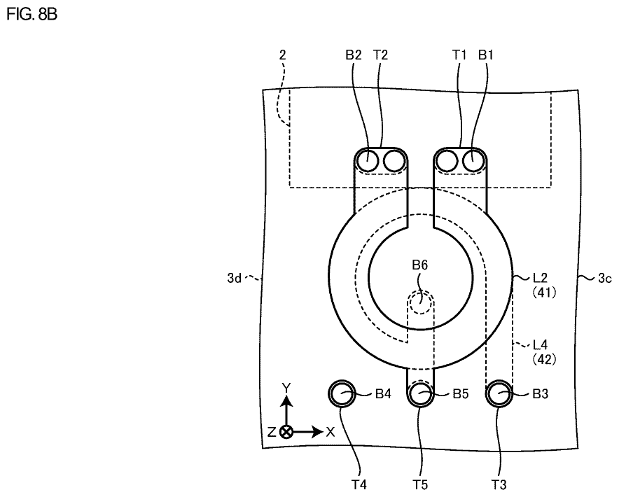

FIG. 8A is an overlapping see-through view of the first wiring layer and the second wiring layer in the third specific example of Embodiment 1. FIG. 8B is an overlapping see-through view of the third wiring layer and the fourth wiring layer in the third specific example of Embodiment 1.

As shown in FIG. 8A, the first inductor L1 of the balanced-side coil 41 provided at the first wiring layer 3a and the third inductor L3 of the unbalanced-side coil 42 provided at the second wiring layer 3b overlap in the Z-direction with the dielectric layer DI interposed therebetween. The first inductor L1 and the third inductor L3 are thereby electromagnetically coupled.

Also, as shown in FIG. 8B, the second inductor L2 of the balanced-side coil 41 provided at the third wiring layer 3c and the fourth inductor L4 of the unbalanced-side coil 42 provided at the fourth wiring layer 3d overlap in the Z-direction with the dielectric layer DI interposed therebetween. The second inductor L2 and the fourth inductor L4 are thereby electromagnetically coupled.

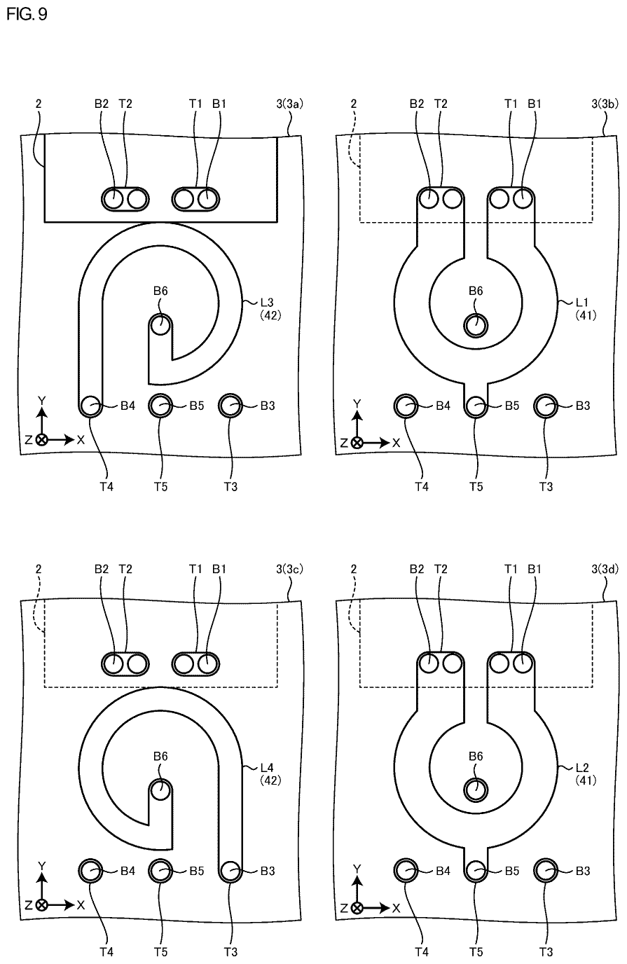

FIG. 9 is a plan view showing a fourth specific example of the balanced-side coil and the unbalanced-side coil provided in the wiring layers of the multilayer substrate of the transformer according to Embodiment 1.

In the fourth specific example shown in FIG. 9, the first inductor L1 at the second wiring layer 3b and the second inductor L2 at the fourth wiring layer 3d are provided in parallel between the first terminal T1 and the second terminal T2.

Specifically, the first inductor L1 at the second wiring layer 3b and the second inductor L2 at the fourth wiring layer 3d are electrically connected by the via B1 provided at the first terminal T1.

Also, the first inductor L1 at the second wiring layer 3b and the second inductor L2 at the fourth wiring layer 3d are electrically connected by the via B2 provided at the second terminal T2.

Also, the first inductor L1 at the second wiring layer 3b and the second inductor L2 at the fourth wiring layer 3d are electrically connected by the via B5 provided at the fifth terminal T5.

The balanced-side coil 41 is thus configured as a parallel circuit of the first inductor L1 at the second wiring layer 3b and the second inductor L2 at the fourth wiring layer 3d.

Also, in the fourth specific example shown in FIG. 9, the third inductor L3 at the first wiring layer 3a and the fourth inductor L4 at the third wiring layer 3c are provided in series between the third terminal T3 and the fourth terminal T4.

Specifically, the third inductor L3 at the first wiring layer 3a and the fourth inductor L4 at the third wiring layer 3c are electrically connected by the via B6.

The unbalanced-side coil 42 is thus configured as a series circuit of the third inductor L3 at the first wiring layer 3a and the fourth inductor L4 at the third wiring layer 3c.

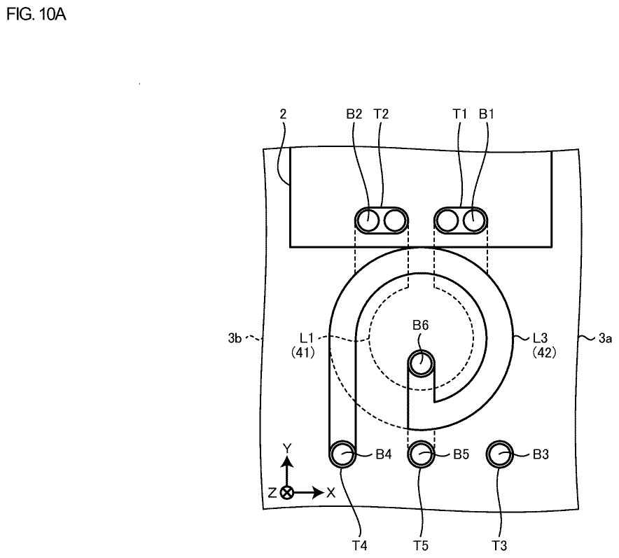

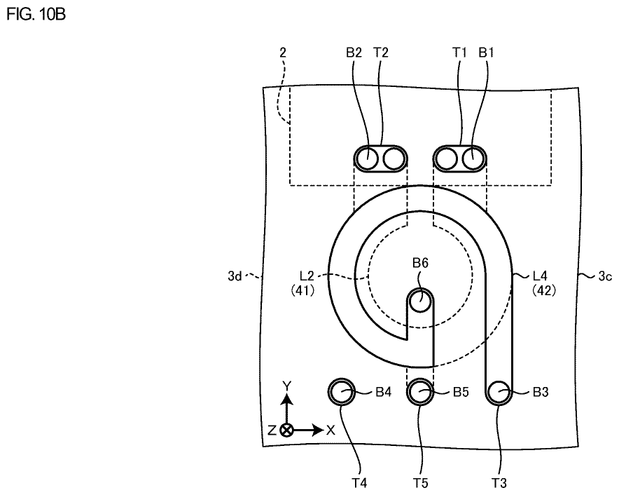

FIG. 10A is an overlapping see-through view of the first wiring layer and the second wiring layer in the fourth specific example of Embodiment 1. FIG. 10B is an overlapping see-through view of the third wiring layer and the fourth wiring layer in the fourth specific example of Embodiment 1.

As shown in FIG. 10A, the third inductor L3 of the unbalanced-side coil 42 provided at the first wiring layer 3a and the first inductor L1 of the balanced-side coil 41 provided at the second wiring layer 3b overlap in the Z-direction with the dielectric layer DI interposed therebetween. The third inductor L3 and the first inductor L1 are thereby electromagnetically coupled.

Also, as shown in FIG. 10B, the fourth inductor L4 of the unbalanced-side coil 42 provided at the third wiring layer 3c and the second inductor L2 of the balanced-side coil 41 provided at the fourth wiring layer 3d overlap in the Z-direction with the dielectric layer DI interposed therebetween. The fourth inductor L4 and the second inductor L2 are thereby electromagnetically coupled.

As described above, the balanced-side coil 41 of the transformer 4 according to Embodiment 1 is configured as a parallel circuit of the first inductor L1 and the second inductor L2 provided at different wiring layers from each other. Also, as described above, the unbalanced-side coil 42 of the transformer 4 according to Embodiment 1 is configured as a series circuit of the third inductor L3 and the fourth inductor L4 provided at different wiring layers from each other.

In the above configuration, the balanced-side coil 41 configured as a parallel circuit of the first inductor L1 and the second inductor L2 and the unbalanced-side coil 42 configured as a series circuit of the third inductor L3 and the fourth inductor L4 overlap in the Z-direction and are thereby electromagnetically coupled, and balanced signals inputted between the first terminal T1 and the second terminal T2 are transformed into an unbalanced signal.

The above configuration allows the inductance value of the balanced-side coil to be small relative to the inductance value of the unbalanced-side coil 42. This can increase the impedance transformation ratio of the transformer 4 and can consequently increase the output of power amplification by the high-frequency module 1.

It is also possible to move a point of resonance of a resonance circuit caused by interwinding capacitance to a higher frequency side. The pass band can thus be widened to the higher-frequency side.

Note that the transformer 4 according to Embodiment 1 may be configured using a surface mount device (SMD).

### Embodiment 2

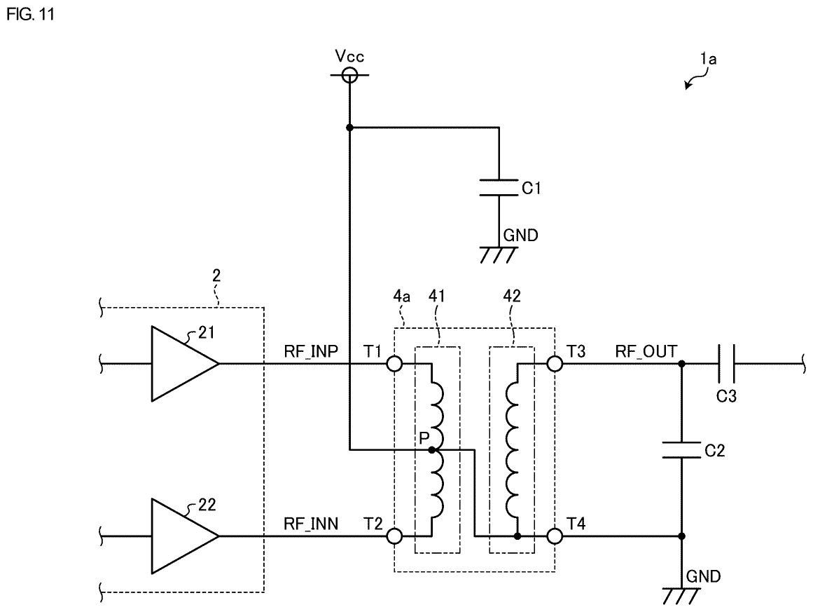

FIG. 11 is a schematic diagram showing an example circuit block configuration of a high-frequency module according to Embodiment 2. Here, details are described for points different from Embodiment 1, and descriptions of the same points as Embodiment 1 may be omitted.

In a high-frequency module 1a according to Embodiment 2, a center tap P of the balanced-side coil 41 is connected to the second end of the unbalanced-side coil 42 (the fourth terminal T4). The DC power supply potential VCC is supplied to the fourth terminal T4 of a transformer 4a. The fourth terminal T4 of the transformer 4a is thereby virtually grounded.

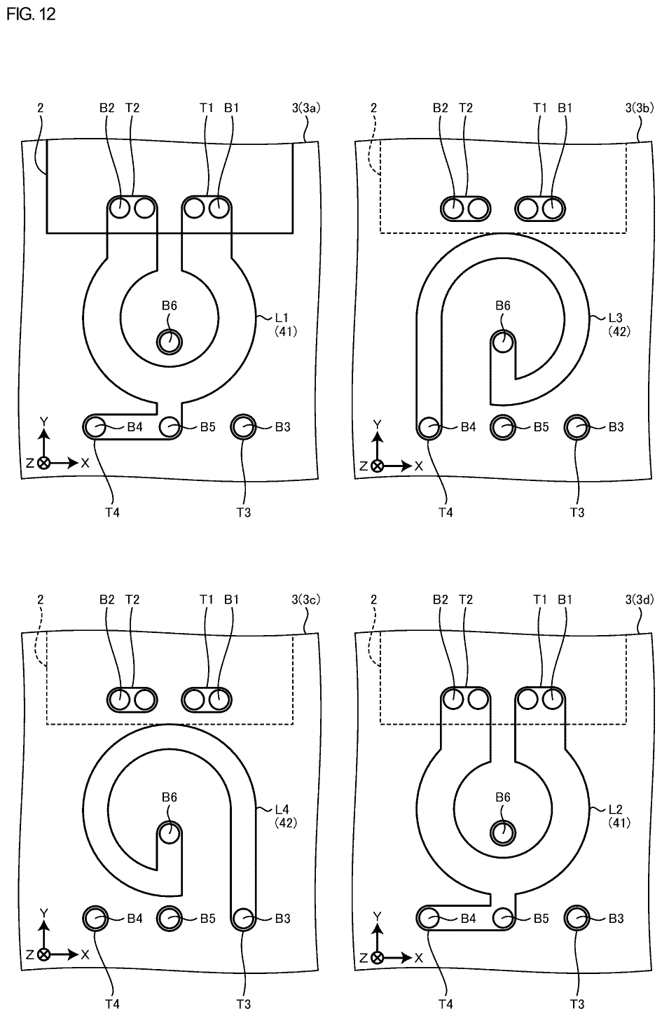

FIG. 12 is a plan view showing a first specific example of the balanced-side coil and the unbalanced-side coil provided in the wiring layers of the multilayer substrate of the transformer according to Embodiment 2.

In the first specific example shown in FIG. 12, the first inductor L1 at the first wiring layer 3a and the second inductor L2 at the fourth wiring layer 3d are provided in parallel between the first terminal T1 and the second terminal T2.

Specifically, the first inductor L1 at the first wiring layer 3a and the second inductor L2 at the fourth wiring layer 3d are electrically connected by the via B1 provided at the first terminal T1.

Also, the first inductor L1 at the first wiring layer 3a and the second inductor L2 at the fourth wiring layer 3d are electrically connected by the via B2 provided at the second terminal T2.

Also, the first inductor L1 at the first wiring layer 3a and the second inductor L2 at the fourth wiring layer 3d are electrically connected by the via B5.

The balanced-side coil 41 is thus configured as a parallel circuit of the first inductor L1 at the first wiring layer 3a and the second inductor L2 at the fourth wiring layer 3d.

Also, in the first specific example shown in FIG. 12, the third inductor L3 at the second wiring layer 3b and the fourth inductor L4 at the third wiring layer 3c are provided in series between the third terminal T3 and the fourth terminal T4.

Specifically, the third inductor L3 at the second wiring layer 3b and the fourth inductor L4 at the third wiring layer 3c are electrically connected by the via B6.

The unbalanced-side coil 42 is thus configured as a series circuit of the third inductor L3 at the second wiring layer 3b and the fourth inductor L4 at the third wiring layer 3c.

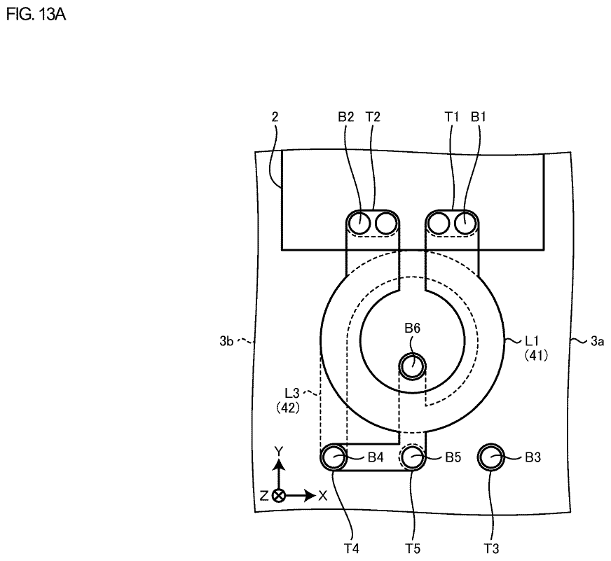

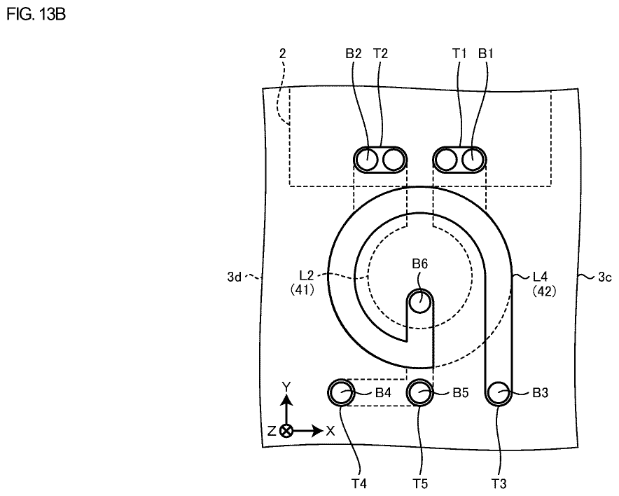

FIG. 13A is an overlapping see-through view of the first wiring layer and the second wiring layer in the first specific example of Embodiment 2. FIG. 13B is an overlapping see-through view of the third wiring layer and the fourth wiring layer in the first specific example of Embodiment 2.

As shown in FIG. 13A, the first inductor L1 of the balanced-side coil 41 provided at the first wiring layer 3a and the third inductor L3 of the unbalanced-side coil 42 provided at the second wiring layer 3b overlap in the Z-direction with the dielectric layer DI interposed therebetween. The first inductor L1 and the third inductor L3 are thereby electromagnetically coupled.

Also, as shown in FIG. 13B, the fourth inductor L4 of the unbalanced-side coil 42 provided at the third wiring layer 3c and the second inductor L2 of the balanced-side coil 41 provided at the fourth wiring layer 3d overlap in the Z-direction with the dielectric layer DI interposed therebetween. The fourth inductor L4 and the second inductor L2 are thereby electromagnetically coupled.

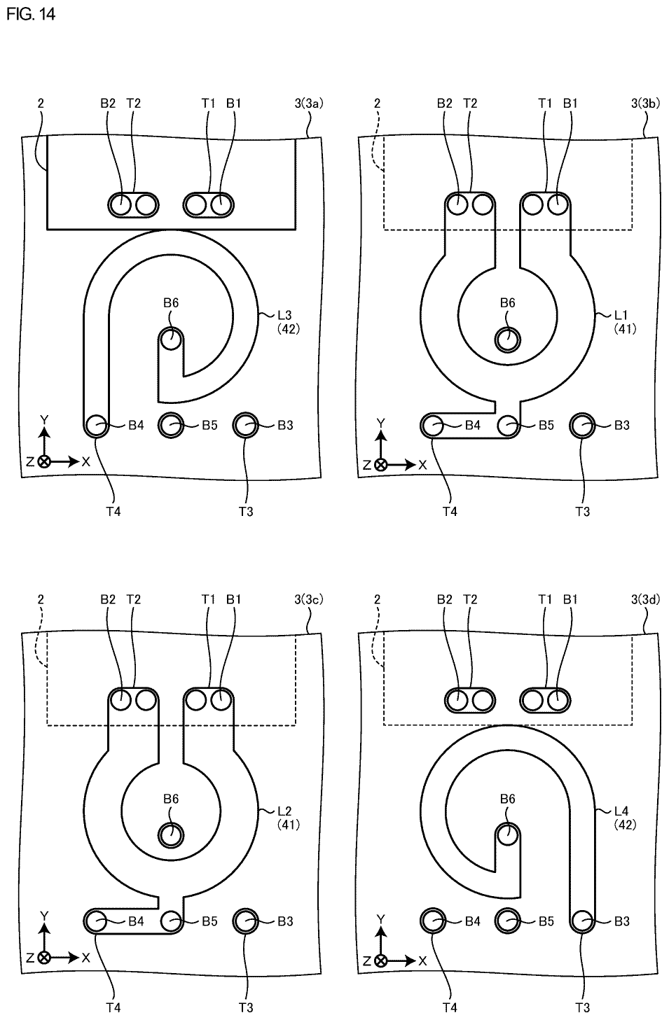

FIG. 14 is a plan view showing a second specific example of the balanced-side coil and the unbalanced-side coil provided in the wiring layers of the multilayer substrate of the transformer according to Embodiment 2.

In the second specific example shown in FIG. 14, the first inductor L1 at the second wiring layer 3b and the second inductor L2 at the third wiring layer 3c are provided in parallel between the first terminal T1 and the second terminal T2.

Specifically, the first inductor L1 at the second wiring layer 3b and the second inductor L2 at the third wiring layer 3c are electrically connected by the via B1 provided at the first terminal T1.

Also, the first inductor L1 at the second wiring layer 3b and the second inductor L2 at the third wiring layer 3c are electrically connected by the via B2 provided at the second terminal T2.

Also, the first inductor L1 at the second wiring layer 3b and the second inductor L2 at the third wiring layer 3c are electrically connected by the via B5.

The balanced-side coil 41 is thus configured as a parallel circuit of the first inductor L1 at the second wiring layer 3b and the second inductor L2 at the third wiring layer 3c.

Also, in the second specific example shown in FIG. 14, the third inductor L3 at the first wiring layer 3a and the fourth inductor L4 at the fourth wiring layer are provided in series between the third terminal T3 and the fourth terminal T4.

Specifically, the third inductor L3 at the first wiring layer 3a and the fourth inductor L4 at the fourth wiring layer 3d are electrically connected by the via B6.

The unbalanced-side coil 42 is thus configured as a series circuit of the third inductor L3 at the first wiring layer 3a and the fourth inductor L4 at the fourth wiring layer 3d.

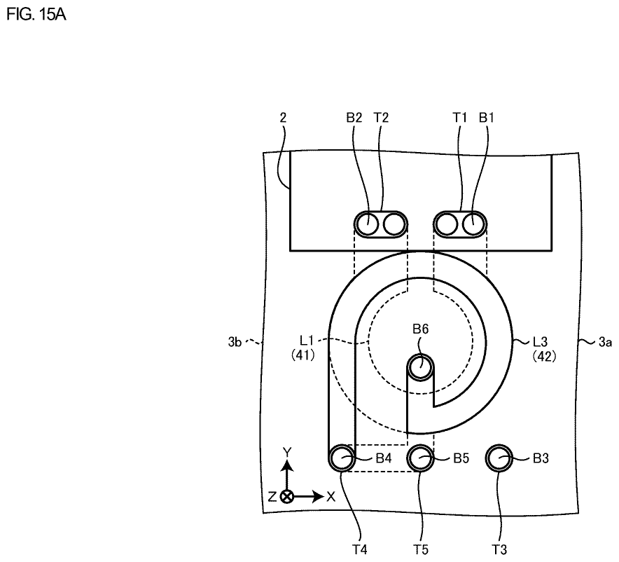

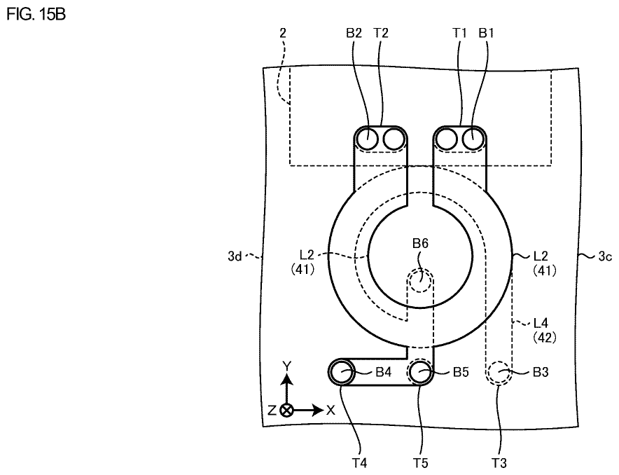

FIG. 15A is an overlapping see-through view of the first wiring layer and the second wiring layer in the second specific example of Embodiment 2. FIG. 15B is an overlapping see-through view of the third wiring layer and the fourth wiring layer of the second specific example of Embodiment 2.

As shown in FIG. 15A, the third inductor L3 of the unbalanced-side coil 42 provided at the first wiring layer 3a and the first inductor L1 of the balanced-side coil 41 provided at the second wiring layer 3b overlap in the Z-direction with the dielectric layer DI interposed therebetween. The third inductor L3 and the first inductor L1 are thereby electromagnetically coupled.

Also, as shown in FIG. 15B, the second inductor L2 of the balanced-side coil 41 provided at the third wiring layer 3c and the fourth inductor L4 of the unbalanced-side coil 42 provided at the fourth wiring layer 3d overlap in the Z-direction with the dielectric layer DI interposed therebetween. The second inductor L2 and the fourth inductor L4 are thereby electromagnetically coupled.

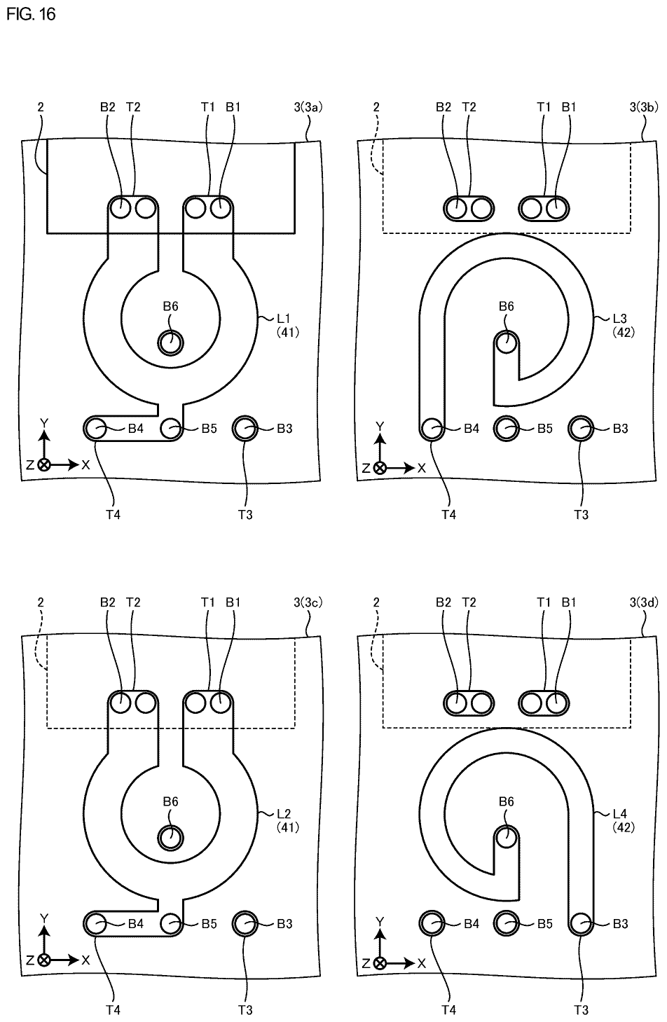

FIG. 16 is a plan view showing a third specific example of the balanced-side coil and the unbalanced-side coil provided in the wiring layers of the multilayer substrate of the transformer according to Embodiment 2.

In the third specific example shown in FIG. 16, the first inductor L1 at the first wiring layer 3a and the second inductor L2 at the third wiring layer 3c are provided in parallel between the first terminal T1 and the second terminal T2.

Specifically, the first inductor L1 at the first wiring layer 3a and the second inductor L2 at the third wiring layer 3c are electrically connected by the via B1 provided at the first terminal T1.

Also, the first inductor L1 at the first wiring layer 3a and the second inductor L2 at the third wiring layer 3c are electrically connected by the via B2 provided at the second terminal T2.

Also, the first inductor L1 at the first wiring layer 3a and the second inductor L2 at the third wiring layer 3c are electrically connected by the via B5.

The balanced-side coil 41 is thus configured as a parallel circuit of the first inductor L1 at the first wiring layer 3a and the second inductor L2 at the third wiring layer 3c.

Also, in the third specific example shown in FIG. 16, the third inductor L3 at the second wiring layer 3b and the fourth inductor L4 at the fourth wiring layer 3d are provided in series between the third terminal T3 and the fourth terminal T4.

Specifically, the third inductor L3 at the second wiring layer 3b and the fourth inductor L4 at the fourth wiring layer 3d are electrically connected by the via B6.

The unbalanced-side coil 42 is thus configured as a series circuit of the third inductor L3 at the second wiring layer 3b and the fourth inductor L4 at the fourth wiring layer 3d.

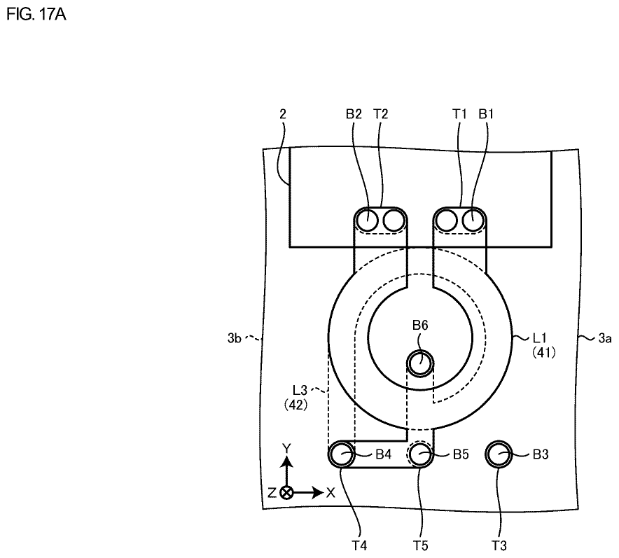

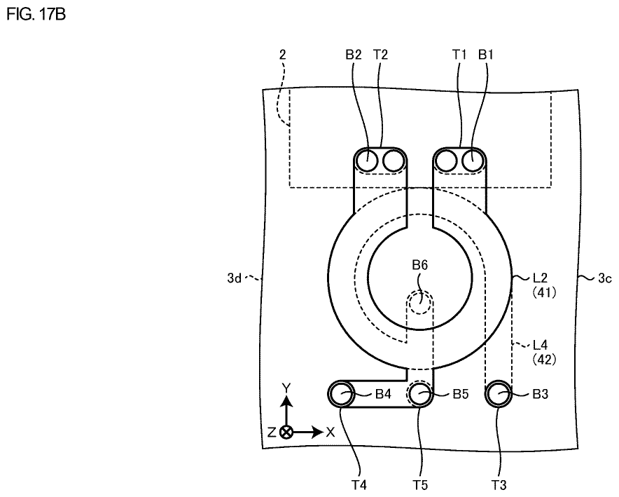

FIG. 17A is an overlapping see-through view of the first wiring layer and the second wiring layer in the third specific example of Embodiment 2. FIG. 17B is an overlapping see-through view of the third wiring layer and the fourth wiring layer in the third specific example of Embodiment 2.

As shown in FIG. 17A, the first inductor L1 of the balanced-side coil 41 provided at the first wiring layer 3a and the third inductor L3 of the unbalanced-side coil 42 provided at the second wiring layer 3b overlap in the Z-direction with the dielectric layer DI interposed therebetween. The first inductor L1 and the third inductor L3 are thereby electromagnetically coupled.

Also, as shown in FIG. 17B, the second inductor L2 of the balanced-side coil 41 provided at the third wiring layer 3c and the fourth inductor L4 of the unbalanced-side coil 42 provided at the fourth wiring layer 3d overlap in the Z-direction with the dielectric layer DI interposed therebetween. The second inductor L2 and the fourth inductor L4 are thereby electromagnetically coupled.

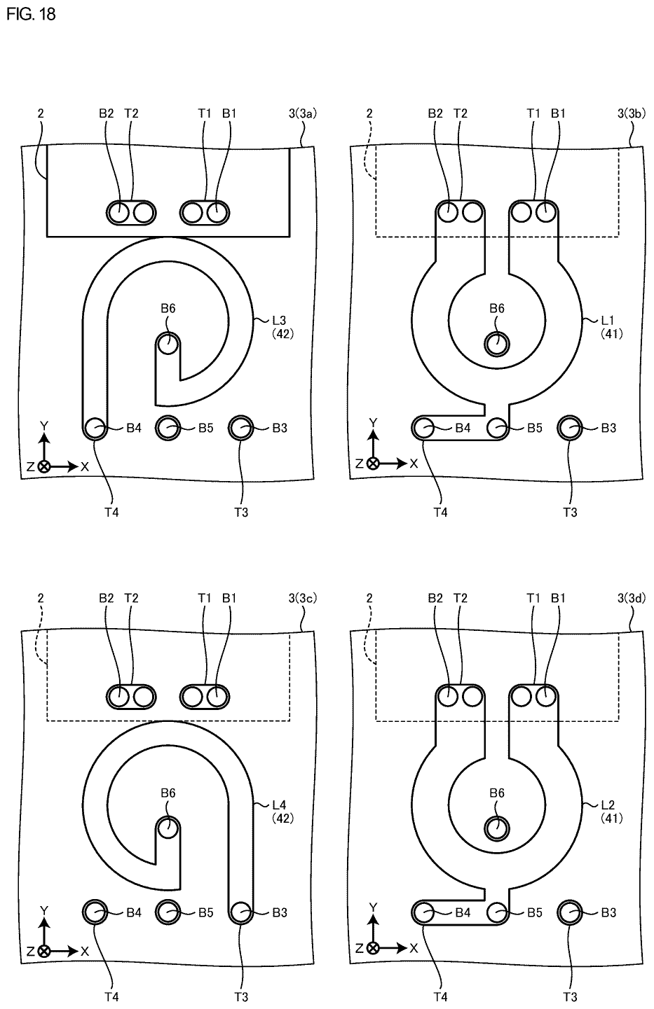

FIG. 18 is a plan view showing a fourth specific example of the balanced-side coil and the unbalanced-side coil provided in the wiring layers of the multilayer substrate of the transformer according to Embodiment 2.

In the fourth specific example shown in FIG. 18, the first inductor L1 at the second wiring layer 3b and the second inductor L2 at the fourth wiring layer 3d are provided in parallel between the first terminal T1 and the second terminal T2.

Specifically, the first inductor L1 at the second wiring layer 3b and the second inductor L2 at the fourth wiring layer 3d are electrically connected by the via B1 provided at the first terminal T1.

Also, the first inductor L1 at the second wiring layer 3b and the second inductor L2 at the fourth wiring layer 3d are electrically connected by the via B2 provided at the second terminal T2.

Also, the first inductor L1 at the second wiring layer 3b and the second inductor L2 at the fourth wiring layer 3d are electrically connected by the via B5.

The balanced-side coil 41 is thus configured as a parallel circuit of the first inductor L1 at the second wiring layer 3b and the second inductor L2 at the fourth wiring layer 3d.

Also, in the fourth specific example shown in FIG. 18, the third inductor L3 at the first wiring layer 3a and the fourth inductor L4 at the third wiring layer 3c are provided in series between the third terminal T3 and the fourth terminal T4.

Specifically, the third inductor L3 at the first wiring layer 3a and the fourth inductor L4 at the third wiring layer 3c are electrically connected by the via B6.

The unbalanced-side coil 42 is thus configured as a series circuit of the third inductor L3 at the first wiring layer 3a and the fourth inductor L4 at the third wiring layer 3c.

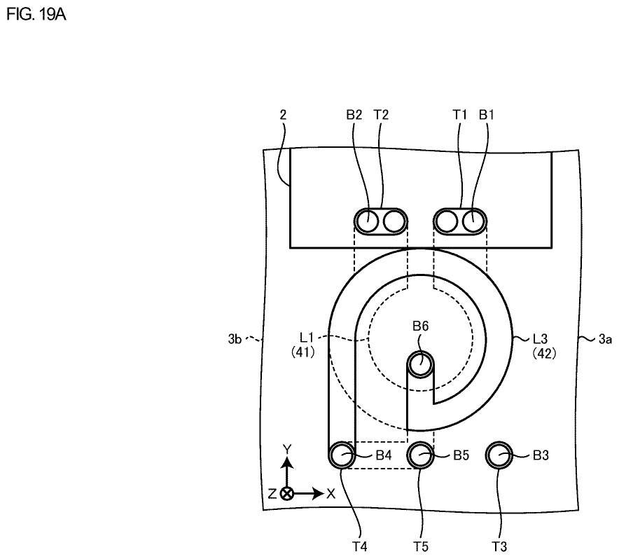

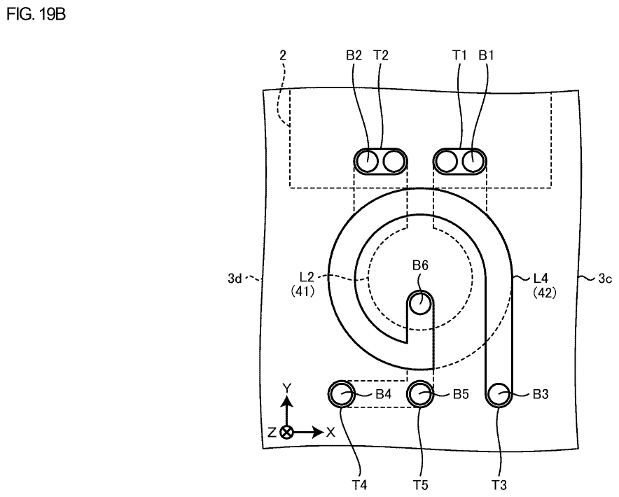

FIG. 19A is an overlapping see-through view of the first wiring layer and the second wiring layer in the fourth specific example of Embodiment 2. FIG. 19B is an overlapping see-through view of the third wiring layer and the fourth wiring layer in the fourth specific example of Embodiment 2.

As shown in FIG. 19A, the third inductor L3 of the unbalanced-side coil 42 provided at the first wiring layer 3a and the first inductor L1 of the balanced-side coil 41 provided at the second wiring layer 3b overlap in the Z-direction with the dielectric layer DI interposed therebetween. The third inductor L3 and the first inductor L1 are thereby electromagnetically coupled.

Also, as shown in FIG. 19B, the fourth inductor L4 of the unbalanced-side coil 42 provided at the third wiring layer 3c and the second inductor L2 of the balanced-side coil 41 provided at the fourth wiring layer 3d overlap in the Z-direction with the dielectric layer DI interposed therebetween. The fourth inductor L4 and the second inductor L2 are thereby electromagnetically coupled.

As described above, the balanced-side coil 41 of the transformer 4 according to Embodiment 2 is, like the balanced-side coil 41 of the transformer 4 according to Embodiment 1, configured as a parallel circuit of the first inductor L1 and the second inductor L2 provided at different wiring layers from each other. Also, as described above, the unbalanced-side coil 42 of the transformer 4 according to Embodiment 1 is, like the unbalanced-side coil 42 of the transformer 4 according to Embodiment 1, configured as a series circuit of the third inductor L3 and the fourth inductor L4 provided at different wiring layers from each other.

In the above configuration, the balanced-side coil 41 configured as a parallel circuit of the first inductor L1 and the second inductor L2 and the unbalanced-side coil 42 configured as a series circuit of the third inductor L3 and the fourth inductor L4 overlap in the Z-direction and are thereby electromagnetically coupled, and balanced signals inputted between the first terminal T1 and the second terminal T2 are transformed into an unbalanced signal.

As with Embodiment 1, the above configuration allows the inductance value of the balanced-side coil to be small relative to the inductance value of the unbalanced-side coil 42. This can increase the impedance transformation ratio of the transformer 4 and can consequently increase the output of power amplification by the high-frequency module 1.

It is also possible to move a point of resonance of a resonance circuit caused by interwinding capacitance to a higher frequency side. The pass band can thus be widened to the higher-frequency side.

### Modification

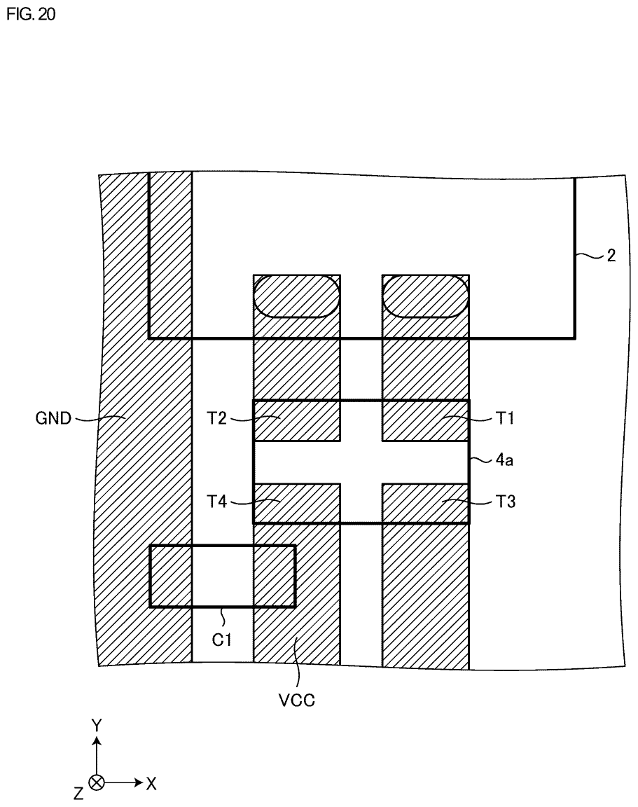

FIG. 20 is a plan view showing an example arrangement of components on a multilayer substrate of a high-frequency module according to a modification of Embodiment 2. In the example shown in FIG. 20, the transformer 4a is configured of a surface mount device (SMD), and the capacitor C1 is provided near the fourth terminal T4.

When the transformer 4a according to Embodiment 2 is configured as an SMD, the number of terminals can be reduced compared to when the transformer 4 according to Embodiment 1 is configured as an SMD. Specifically, the fifth terminal T5 of the transformer 4 according to Embodiment 1 is unneeded.

In the configuration according to Embodiment 2, if the supply path of the DC power supply potential VCC between the fourth terminal T4 of the transformer 4a and the capacitor C1 is long, the inductance component in the supply path of the DC power supply potential VCC may become non-negligible, resulting in degraded characteristics due to RF coupling between the balanced-side coil 41 and the unbalanced-side coil 42.

As shown in FIG. 20, when the transformer 4a is configured as an SMD and the capacitor C1 provided between the supply path of the DC power supply potential VCC and the ground potential GND is disposed adjacent to the transformer 4a, RF coupling between the balanced-side coil 41 and the unbalanced-side coil 42 is mitigated. This enables less degradation of characteristics caused by a reduction in the terminals of the transformer 4a according to Embodiment 2.

Note that the embodiments described above have been given to facilitate understanding of the present disclosure and not for the present disclosure to be interpreted in a limited way. The present disclosure can be modified or improved without departing from the gist thereof, and the present disclosure includes such equivalents as well.

The present disclosure can be configured as follows as described above or alternatively to the above-described configurations.
(1) A transformer according to one aspect of the present disclosure is a transformer provided at a multilayer substrate having a plurality of wiring layers laminated with a dielectric layer interposed in between. The transformer includes a balanced-side coil provided between a first terminal and a second terminal and an unbalanced-side coil provided between a third terminal and a fourth terminal. The balanced-side coil is configured such that a first inductor and a second inductor provided at different ones of the wiring layers are connected in parallel, and the unbalanced-side coil is configured such that a third inductor and a fourth inductor provided at different ones of the wiring layers are connected in series.

This configuration allows the inductance value of the balanced-side coil to be small relative to the inductance value of the unbalanced-side coil. This can increase the impedance transformation ratio of the transformer.

It is also possible to move a point of resonance of a resonance circuit caused by interwinding capacitance to a higher frequency side. The pass band can thus be widened to the higher-frequency side.
(2) In the transformer according to the above (1), a center tap of the balanced-side coil is connected to a fifth terminal.
(3) In the transformer according to the above (1), a center tap of the balanced-side coil is connected to the fourth terminal.

This configuration can reduce the number of terminals of the transformer.
(4) In the transformer according to the above (2) or (3), the transformer is an SMD formed by an LTCC substrate.
(5) In the transformer according to the above (4), the multilayer substrate includes a first wiring layer, a second wiring layer provided on the first wiring layer with a dielectric layer interposed in between, a third wiring layer provided on the second wiring layer with a dielectric layer interposed in between, and a fourth wiring layer provided on the third wiring layer with a dielectric layer interposed in between.
(6) In the transformer according to the above (5), in the multilayer substrate, in a plan view, the first inductor and the third inductor overlap with the dielectric layer interposed in between, and the second inductor and the fourth inductor overlap with the dielectric layer interposed in between.

In this configuration, the first inductor and the third inductor overlapping in a plan view with the dielectric layer interposed therebetween are electromagnetically coupled, and the second inductor and the fourth inductor overlapping in a plan view with the dielectric layer interposed therebetween are electromagnetically coupled. Thus, balanced signals inputted between the first terminal and the second terminal are transformed into an unbalanced signal.
(7) In the transformer according to the above (6), the first inductor is provided at the first wiring layer, the second inductor is provided at the fourth wiring layer, the third inductor is provided at the second wiring layer, and the fourth inductor is provided at the third wiring layer.
(8) In the transformer according to the above (6), the first inductor is provided at the second wiring layer, the second inductor is provided at the third wiring layer, the third inductor is provided at the first wiring layer, and the fourth inductor is provided at the fourth wiring layer.
(9) In the transformer according to the above (6), the first inductor is provided at the first wiring layer, the second inductor is provided at the third wiring layer, the third inductor is provided at the second wiring layer, and the fourth inductor is provided at the fourth wiring layer.
(10) In the transformer according to the above (6), the first inductor is provided at the second wiring layer, the second inductor is provided at the fourth wiring layer, the third inductor is provided at the first wiring layer, and the fourth inductor is provided at the third wiring layer.
(11) A high-frequency module according to one aspect of the present disclosure is a high-frequency module including: the transformer according to the above (2) and a power amplification circuit including a first amplifier and a second amplifier, in which in the transformer, a first balanced signal outputted from the first amplifier is inputted to the first terminal, a second balanced signal outputted from the second amplifier is inputted to the second terminal, the fourth terminal is connected to a ground potential, a DC power supply potential is supplied to the fifth terminal, and an unbalanced signal obtained by synthesis of the first balanced signal and the second balanced signal is outputted from the third terminal.

This configuration allows the inductance value of the balanced-side coil to be small relative to the inductance value of the unbalanced-side coil. This can increase the impedance transformation ratio of the transformer and can consequently increase the output of power amplification by the high-frequency module.

It is also possible to move a point of resonance of a resonance circuit caused by interwinding capacitance to a higher frequency side. The pass band can thus be widened to the higher-frequency side.
(12) A high-frequency module according to one aspect of the present disclosure is a high-frequency module including the transformer according to the above (3) and a power amplification circuit including a first amplifier and a second amplifier. In the transformer, a first balanced signal outputted from the first amplifier is inputted to the first terminal, a second balanced signal outputted from the second amplifier is inputted to the second terminal, a DC power supply potential is supplied to the fourth terminal, and an unbalanced signal obtained by synthesis of the first balanced signal and the second balanced signal is outputted from the third terminal.

This configuration allows the inductance value of the balanced-side coil to be small relative to the inductance value of the unbalanced-side coil. This can increase the impedance transformation ratio of the transformer and can consequently increase the output of power amplification by the high-frequency module.

It is also possible to move a point of resonance of a resonance circuit caused by interwinding capacitance to a higher frequency side. The pass band can thus be widened to the higher-frequency side.
(13) In the high-frequency module according to the above (11) or (12), the transformer is an SMD formed by an LTCC substrate.
(14) In the high-frequency module according to the above (11) or (12), the multilayer substrate includes a first wiring layer, a second wiring layer provided on the first wiring layer with a dielectric layer interposed in between, a third wiring layer provided on the second wiring layer with a dielectric layer interposed in between, and a fourth wiring layer provided on the third wiring layer with a dielectric layer interposed in between.
(15) In the high-frequency module according to the above (14), in the multilayer substrate, in a plan view, the first inductor and the third inductor overlap with a dielectric layer interposed in between, and the second inductor and the fourth inductor overlap with a dielectric layer interposed in between.

In this configuration, the first inductor and the third inductor overlapping in a plan view with the dielectric layer interposed therebetween are electromagnetically coupled, and the second inductor and the fourth inductor overlapping in a plan view with the dielectric layer interposed therebetween are electromagnetically coupled. Thus, balanced signals inputted between the first terminal and the second terminal are transformed into an unbalanced signal.
(16) In the high-frequency module according to the above (15), the first inductor is provided at the first wiring layer, the second inductor is provided at the fourth wiring layer, the third inductor is provided at the second wiring layer, and the fourth inductor is provided at the third wiring layer.
(17) In the high-frequency module according to the above (15), the first inductor is provided at the second wiring layer, the second inductor is provided at the third wiring layer, the third inductor is provided at the first wiring layer, and the fourth inductor is provided at the fourth wiring layer.
(18) In the high-frequency module according to the above (15), the first inductor is provided at the first wiring layer, the second inductor is provided at the third wiring layer, the third inductor is provided at the second wiring layer, and the fourth inductor is provided at the fourth wiring layer.
(19) In the high-frequency module according to the above (15), the first inductor is provided at the second wiring layer, the second inductor is provided at the fourth wiring layer, the third inductor is provided at the first wiring layer, and the fourth inductor is provided at the third wiring layer.
(20) In the high-frequency module according to the above (15), the power amplification circuit is a differential Doherty amplification circuit, and the first amplifier and the second amplifier each include a carrier amplifier and a peaking amplifier.
(21) In the high-frequency module according to the above (15), a capacitor provided between a supply path of the DC power supply potential and a ground potential is disposed adjacent to the transformer.

This configuration enables less degradation of characteristics caused by a reduction in the terminals of the transformer.

The present disclosure can achieve a transformer and a high-frequency module capable of implementing a differential power amplification circuit supporting a higher frequency or output.

What is claimed is:

1. A transformer at a multilayer substrate having a plurality of wiring layers laminated with a dielectric layer interposed in between, the transformer comprising:
a balanced-side coil between a first terminal and a second terminal; and
an unbalanced-side coil between a third terminal and a fourth terminal, wherein
the balanced-side coil is configured such that a first inductor and a second inductor at different ones of the wiring layers are connected in parallel, and
the unbalanced-side coil is configured such that a third inductor and a fourth inductor at different ones of the wiring layers are connected in series.

2. The transformer according to claim 1, wherein
a center tap of the balanced-side coil is connected to a fifth terminal.

3. The transformer according to claim 1, wherein
a center tap of the balanced-side coil is connected to the fourth terminal.

4. The transformer according to claim 2, wherein
the transformer is an SMD including an LTCC substrate.

5. The transformer according to claim 4, wherein
the multilayer substrate includes
a first wiring layer,
a second wiring layer on the first wiring layer with a dielectric layer interposed in between,
a third wiring layer on the second wiring layer with a dielectric layer interposed in between, and
a fourth wiring layer on the third wiring layer with a dielectric layer interposed in between.

6. The transformer according to claim 5, wherein
in the multilayer substrate, in a plan view,
the first inductor and the third inductor overlap with the dielectric layer interposed in between, and
the second inductor and the fourth inductor overlap with the dielectric layer interposed in between.

7. The transformer according to claim 6, wherein
the first inductor is at the first wiring layer,
the second inductor is at the fourth wiring layer,
the third inductor is at the second wiring layer, and
the fourth inductor is at the third wiring layer.

8. The transformer according to claim 6, wherein
the first inductor is at the second wiring layer,
the second inductor is at the third wiring layer,
the third inductor is at the first wiring layer, and
the fourth inductor is at the fourth wiring layer.

9. The transformer according to claim 6, wherein
the first inductor is at the first wiring layer,
the second inductor is at the third wiring layer,
the third inductor is at the second wiring layer, and
the fourth inductor is at the fourth wiring layer.

10. The transformer according to claim 6, wherein
the first inductor is at the second wiring layer,
the second inductor is at the fourth wiring layer,
the third inductor is at the first wiring layer, and
the fourth inductor is at the third wiring layer.

11. A high-frequency module comprising:
the transformer according to claim 2; and
a power amplification circuit including a first amplifier and a second amplifier,
wherein in the transformer,
a first balanced signal outputted from the first amplifier is inputted to the first terminal,
a second balanced signal outputted from the second amplifier is inputted to the second terminal,
the fourth terminal is connected to a ground potential,
a DC power supply potential is supplied to the fifth terminal, and
an unbalanced signal obtained by synthesis of the first balanced signal and the second balanced signal is outputted from the third terminal.

12. A high-frequency module comprising:
the transformer according to claim 3; and
a power amplification circuit including a first amplifier and a second amplifier,
wherein in the transformer,
a first balanced signal outputted from the first amplifier is inputted to the first terminal,
a second balanced signal outputted from the second amplifier is inputted to the second terminal,
a DC power supply potential is supplied to the fourth terminal, and
an unbalanced signal obtained by synthesis of the first balanced signal and the second balanced signal is outputted from the third terminal.

13. The high-frequency module according to claim 11, wherein
the transformer is an SMD including an LTCC substrate.

14. The high-frequency module according to claim 11, wherein
the multilayer substrate includes
a first wiring layer,
a second wiring layer on the first wiring layer with a dielectric layer interposed in between,
a third wiring layer on the second wiring layer with a dielectric layer interposed in between, and
a fourth wiring layer on the third wiring layer with a dielectric layer interposed in between.

15. The high-frequency module according to claim 14, wherein
in the multilayer substrate, in a plan view,
the first inductor and the third inductor overlap with a dielectric layer interposed in between, and
the second inductor and the fourth inductor overlap with a dielectric layer interposed in between.

16. The high-frequency module according to claim 15, wherein
the first inductor is at the first wiring layer,
the second inductor is at the fourth wiring layer,
the third inductor is at the second wiring layer, and
the fourth inductor is at the third wiring layer.

17. The high-frequency module according to claim 15, wherein
the first inductor is at the second wiring layer,
the second inductor is at the third wiring layer,
the third inductor is at the first wiring layer, and
the fourth inductor is at the fourth wiring layer.

18. The high-frequency module according to claim 15, wherein
the first inductor is at the first wiring layer,
the second inductor is at the third wiring layer,
the third inductor is at the second wiring layer, and
the fourth inductor is at the fourth wiring layer.

19. The high-frequency module according to claim 15, wherein
the first inductor is at the second wiring layer,
the second inductor is at the fourth wiring layer,
the third inductor is at the first wiring layer, and
the fourth inductor is at the third wiring layer.

20. The high-frequency module according to claim 15, wherein
the power amplification circuit is a differential Doherty amplification circuit, and
the first amplifier and the second amplifier each include a carrier amplifier and a peaking amplifier.

21. The high-frequency module according to claim 15, further comprising:
a capacitor between a supply path of the DC power supply potential and a ground potential and adjacent to the transformer.
